(19) United States
(12) Patent Application Publication
(10) Pub. No.: US 2013/0163198 A1
(43) Pub. Date: Jun. 27, 2013

(54) SERVER ASSEMBLY AND RACK OF THE SAME

(71) Applicants: XIAO-ZHENG LI, Shenzhen City (CN); WEN-TANG PENG, Tu-Cheng (TW)

(72) Inventors: XIAO-ZHENG LI, Shenzhen City (CN); WEN-TANG PENG, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/434,870

(22) Filed: Mar. 30, 2012

(30) Foreign Application Priority Data
Dec. 24, 2011 (CN) 201110438367.8

(51) Int. Cl. G06F 1/16; H05K 7/18

(52) U.S. Cl. 361/679.58; 211/26

(57) ABSTRACT

A server assembly includes a rack and a server unit movably received in the rack. The rack includes two slide rails arranged at opposite sides of the rack, and a mounting plate fixed at a rear end of the rack. A connecting module is movably attached to the mounting plate and faces the server unit. The connecting module includes a connector. A connecting portion is set on a rear end of the server unit. The server unit is slid into the rack, to allow the connecting portion to be connected to the connector.

### BACKGROUND

1. Technical Field

The present disclosure relates to a server assembly and a rack of the server assembly.

2. Description of Related Art

A server includes a rack and at least one server unit slidably mounted in the rack. When the server unit is inserted into the rack, the connectors of the server unit and the connecting portions on the backplane of the rack cannot be seen, so the connectors of the server unit may not be properly aligned with the corresponding connecting portions, which can cause damage to the connectors.

### BRIEF DESCRIPTION OF THE DRAWINGS

Many aspects of the present embodiments can be better understood with reference to the drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an exploded, isometric view of an embodiment of a server assembly, wherein the server assembly includes a rack and a server unit.

FIG. 2 is an exploded, isometric view of the rack of FIG. 1, but viewed from another aspect.

FIG. 3 is an assembled, isometric view of FIG. 2.

FIG. 4 is an assembled, isometric view of FIG. 1.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

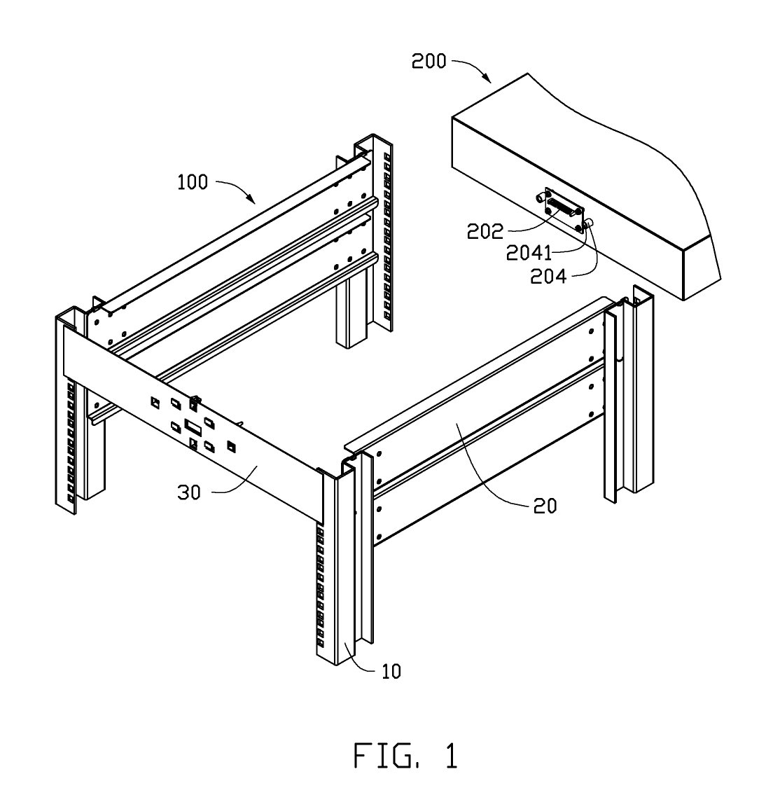

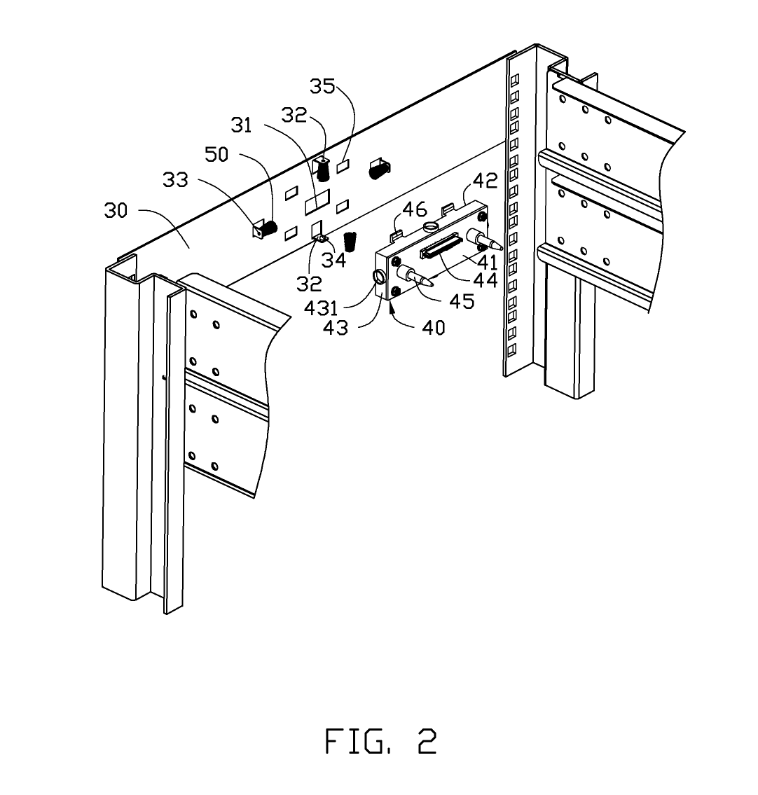

Referring to FIGS. 1 and 2, an embodiment of a server assembly includes a rack 100 and a server unit 200 mounted in the rack 100.

The server unit 200 includes a rectangular connecting portion 202 set on a middle of a rear end of the server unit 200. Two guiding poles 204 are set on the rear end and located at opposite sides of the connecting portion 202. Each guiding pole 204 axially defines a guiding hole 2041.

The rack 100 includes four upright supporting posts 10. A slide rail 20 is perpendicularly fixed between two supporting posts 10 at each side of the rack 100. A mounting plate 30 is perpendicularly fixed between two supporting posts 10 at a rear end of the rack 100. The slide rails 20 at opposite sides of the rack 100 and the mounting plate 30 are level with one another. A rectangular through hole 31 is defined in a middle of the mounting plate 30. Two first pieces 32 extend perpendicularly from the mounting plate 30, respectively positioned above and below the through hole 31, and substantially parallel to the lengthwise direction of the mounting plate 30. Two second pieces 33 extend perpendicularly from the mounting plate 30, respectively positioned at opposite sides of the through hole 31, and substantially perpendicular to the lengthwise direction of the mounting plate 30. A protrusion 34 extends from each of the first pieces 32 towards the other first piece 32. A protrusion 34 extends from each of the second pieces 33 toward the other second piece 33. Four rectangular locking slots 35 are defined in the mounting plate 30, around the through hole 31 and respectively adjacent to four corners of the through hole 31.

A connecting module 40 is movably mounted on an inner side of the mounting plate 30 through four resilient members 50. The connecting module 40 includes a rectangular first side 41, a rectangular second side 42 parallel to the first side 41, and four lateral surfaces 43 connected between corresponding lateral sides of the first side 41 and the second side 42. A connector 44 is arranged on a middle of the connecting module 40 and extends through the first side 41 and the second side 42. Two guiding pins 45 extend from the first side 41, at opposite sides of the connector 44. A distal end of each guiding pin 45 opposite to the first side 41 is tapered. Four L-shaped locking blocks 46 extend from top and bottom lateral sides of the second side 42. A ring shaped receiving portion 431 is formed on each lateral surface 43. In this embodiment, the resilient members 50 are conical spiral springs.

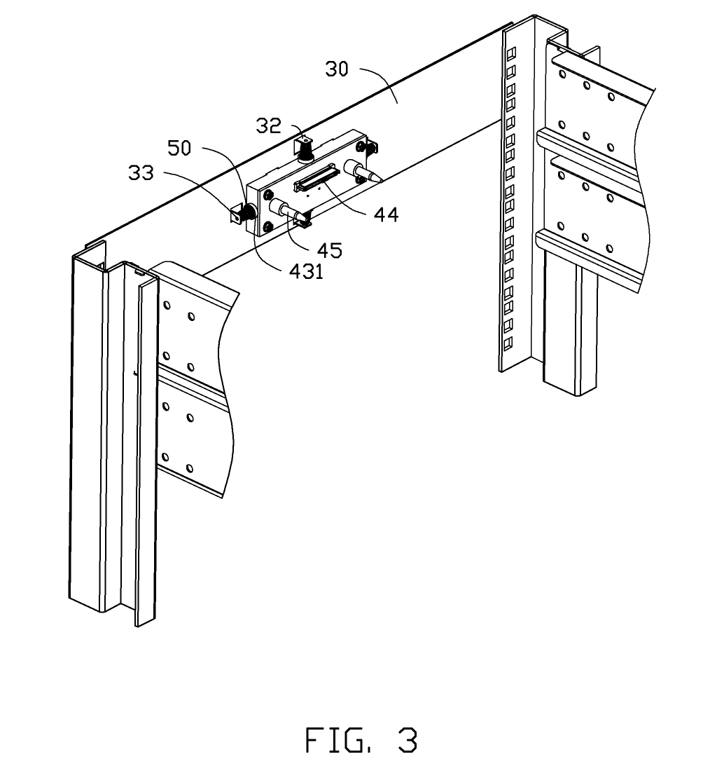

Referring to FIG. 3, in assembly, the locking blocks 46 are movably engaged in the corresponding locking slots 35. A small end of each resilient member 50 abuts against a corresponding tab 34, and fits about the corresponding protrusion 34. A large second end of the resilient member 50 is received in a corresponding receiving portion 431. Therefore the connecting module 40 is movably mounted on the mounting plate 30. The connector 44 at the second side 42 is exposed through the through hole 31.

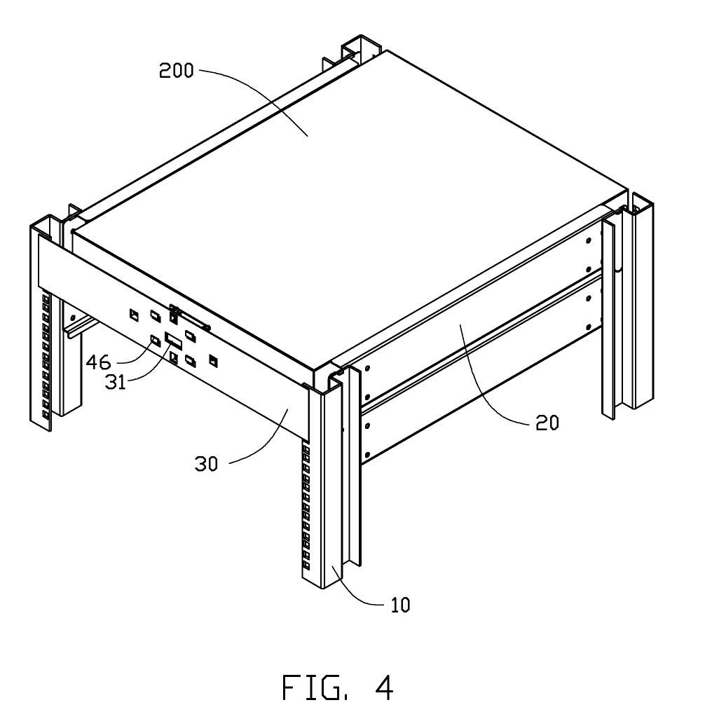

Referring to FIG. 4, in assembling the server unit 200, the server unit 200 is slid into the rack 100. Opposite sides of the server unit 200 are slidably supported by the slide rails 20. The connecting portion 202 faces the mounting plate 30. The guiding pins 45 are inserted into the corresponding guiding holes 2041, under guide of the tapered distal ends of the guiding pins 45. The server unit 200 is further slid into the rack 100, until the connecting portion 202 is connected to the connector 44.

In this embodiment, the connecting module 40 is movable to align the connecting portion 202 with the connector 44, which can prevent damage to the connector 44 and the connecting portion 202 during insertion of the server unit 200 into the rack 100.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A server rack, comprising:
a plurality of supporting posts;
a mounting plate fixed between two rear ones of the supporting posts, wherein the mounting plate defines a through hole; and
a connecting module movably mounted on the mounting plate, wherein the connecting module comprises a connector, a first side of the connector is exposed through the through hole, a second side of the connector is configured for connecting a server unit received among the supporting posts.

2. The server rack of claim 1, wherein a plurality of resilient members are arranged between the connecting module and the mounting plate.

3. The server rack of claim 2, wherein two first pieces extend perpendicularly from the mounting plate, the first pieces are respectively positioned above and below the through hole and substantially parallel to a lengthwise direction of the mounting plate, two second pieces extend perpendicularly from the mounting plate, the second pieces are respectively positioned at opposite sides of the through hole and substantially perpendicular to the lengthwise direction of the mounting plate, a protrusion extends from an inner side of each of the first pieces and the second pieces, the connecting module comprises a first side, a second side opposite to the first side, and four lateral surfaces connected between corresponding lateral sides of the first side and the second side, a ring shaped receiving portion is formed on each of the lateral surfaces, a first end of each resilient member abuts against a corresponding tab and fits about the corresponding protrusion, a second end of the resilient member is received in a corresponding receiving portion.

4. The server rack of claim 3, wherein four locking slots are defined in the mounting plate around the through hole, the connector is arranged on a middle of the connecting module and extends through the first side and the second side, four L-shaped locking blocks extend from opposite lateral sides of the second side, the locking blocks are movably engaged in the corresponding locking slots.

5. The server rack of claim 3, wherein the resilient members are conical spiral springs.

6. The server rack of claim 3, wherein two guiding pins extend from the first side of the connecting module and at opposite sides of the connector.

7. The server rack of claim 6, wherein a distal end of each guiding pin opposite to the first side is tapered.

8. A server assembly, comprising:
a rack comprising four supporting posts, a mounting plate fixed between two rear ones of the supporting posts, and two slide rails each mounted to two side ones of the supporting posts;
a connecting module movably mounted on the mounting plate, wherein the connecting module comprises a connector; and
a server unit with a connecting portion set on a rear end of the server unit;
wherein when the server unit is slid into the rack along the slide rails, the connecting portion is operable to be connected to the connector.

9. The server assembly of claim 8, wherein a plurality of resilient members are arranged between the connecting module and the mounting plate.

10. The server assembly of claim 9, wherein two first pieces extend perpendicularly from the mounting plate, the first pieces are respectively positioned above and below the through hole and substantially parallel to a lengthwise direction of the mounting plate, two second pieces extend perpendicularly from the mounting plate, the second pieces are respectively positioned at left and right sides of the through hole and substantially perpendicular to the lengthwise direction of the mounting plate, a protrusion extends from an inner side of each of the first pieces and the second pieces, the connecting module comprises a first side, a second side opposite to the first side, and four lateral surfaces connected between corresponding lateral sides of the first side and the second side, a ring shaped receiving portion is formed on each of the lateral surfaces, a first end of each resilient member abuts against a corresponding tab and fits about the corresponding protrusion, a second end of the resilient member is received in a corresponding receiving portion.

11. The server assembly of claim 10, wherein four locking slots are defined in the mounting plate around the through hole, the connector extends through the first side, four L-shaped locking blocks extend from the second side, the locking blocks are movably engaged in the corresponding locking slots.

12. The server assembly of claim 10, wherein the resilient members are conical spiral springs.

13. The server assembly of claim 10, wherein two guiding pins extend from the first side of the connecting module and at left and right sides of the connector, two guiding poles are set on the rear end of the server unit and at left and right sides of the connecting portion, each guiding portion axially defines a guiding hole, for receiving the corresponding guiding pins.

14. The server assembly of claim 13, wherein a distal end of each guiding pin opposite to the first side is tapered.
